(19) United States
(12) Patent Application Publication
(10) Pub. No.: US 2026/0313832 A1
(43) Pub. Date: Oct. 8, 2026

(54) REGULATING IN-SERIES THERMAL DISSIPATION FOR ENHANCED SYSTEM MANAGEMENT

(71) Applicant: Dell Products L.P., Round Rock, TX (US)

(72) Inventors: BRENNAN TROY ROBERT SEAL, Austin, TX (US); JUSTIN TAYLOR FULWIDER, Round Rock, TX (US); OBINNA UYANNA, Austin, TX (US)

(21) Appl. No.: 19/098,902

(22) Filed: Apr. 2, 2025

(51) Int. Cl. H05K 7/20

(52) U.S. Cl. CPC H05K 7/20263; H05K 7/20136; H05K 7/20254; H05K 7/20272; H05K 7/20281

(57) ABSTRACT

Methods, systems, and devices are provided for thermal management of a data processing system. Such a system may include a plurality of heat generating components, and a liquid cooling loop to thermally manage the plurality of heat generating components. The liquid cooling loop may be adapted to obtain a cooling liquid from an external cooling system, the cooling liquid being cooled to a first temperature, cooling a first heat generating component of the plurality of heat generating components using the cooling liquid to obtain a warmed cooling liquid, cooling the warmed cooling liquid to obtain a re-cooled cooling liquid of a second temperature, and cooling a second heat generating component of the plurality of heat generating components using the re-cooled cooling liquid.

### FIELD

Embodiments disclosed herein relate (generally) to thermal management of data processing systems. More particularly, embodiments disclosed herein relate to systems and methods for mitigating (e.g., heat) damage to data processing systems.

### BACKGROUND

Computing devices may provide computer-implemented services. The computer-implemented services may be used by users of the computing devices and/or devices operably connected to the computing devices. The computer-implemented services may be performed with hardware components such as processors, memory modules, storage devices, and communication devices. The operation of these components and the components of other devices may impact the performance of the computer-implemented services.

### BRIEF DESCRIPTION OF THE DRAWINGS

Embodiments disclosed herein are illustrated by way of example and not limitation in the figures of the accompanying drawings in which like references indicate similar elements.

FIGS. 1A-1B show diagrams illustrating a data processing system in accordance with an embodiment.

FIG. 2 shows a diagram illustrating a data processing system and a liquid cooling loop in accordance with an embodiment.

FIGS. 3A-3B show diagrams illustrating a liquid cooling loop in accordance with an embodiment.

FIG. 4 shows a block diagram illustrating a data processing system in accordance with an embodiment.

### DETAILED DESCRIPTION

Various embodiments will be described with reference to details discussed below, and the accompanying drawings will illustrate the various embodiments. The following description and drawings are illustrative and are not to be construed as limiting. Numerous specific details are described to provide a thorough understanding of various embodiments. However, in certain instances, well-known or conventional details are not described in order to provide a concise discussion of embodiments disclosed herein.

Reference in the specification to “one embodiment” or “an embodiment” means that a particular feature, structure, or characteristic described in conjunction with the embodiment can be included in at least one embodiment. The appearances of the phrases “in one embodiment” and “an embodiment” in various places in the specification do not necessarily all refer to the same embodiment.

References to an “operable connection” or “operably connected” means that a particular device is able to communicate with one or more other devices. The devices themselves may be directly connected to one another or may be indirectly connected to one another through any number of intermediary devices, such as in a network topology.

In general, embodiments disclosed herein relate to methods and systems for managing a data processing system. The data processing system may provide computer-implemented services. To provide the computer-implemented services, the data processing system may need to operate in operable conditions. These operable conditions may be predetermined operating conditions in which the data processing system is known to operates optimally (e.g., an optimal thermal range within which a data processing system’s operation may result in the computer-implemented services being provided as expected and/or desired by a consumer of such services).

To place the data processing system in the operable conditions, the data processing system may include, and/or accommodate the installation of, a liquid cooling system. The liquid cooling system may place the data processing system in the operable conditions by providing a means for regulating heat that is generated by hardware components of the data processing system. For example, heat may be generated by the hardware components while the hardware components process workloads and/or otherwise facilitate functionalities of the data processing system that permit the data processing system to provide the computer-implemented services.

If the generated heat is not properly regulated (e.g., dissipated), the hardware components may be damaged by the generated heat as more heat is continuously generated during the data processing system’s operation, and may therefore result in a buildup of heat that is beyond the thermal range for optimal operation of the data processing system. Consequently, this buildup of heat may result in the hardware components being damaged.

Consequently, damage to the hardware components may cause workloads performed by the hardware components and/or facilitated functionalities of the data processing system to be lost (referred to as “workload loss”) and/or otherwise deprecated (resulting in less-than-optimal operation of the data processing system at best).

Such loss and/or deprecation may, in turn, negatively impact (e.g., delay and/or prevent entirely) the data processing system’s providing of the computer-implemented services.

To increase the likelihood of placing the data processing system in the operable conditions (therefore increasing a likelihood of the computer implemented services being provided as expected and/or desired by a consumer of such services), the liquid cooling system may include, and/or accommodate the installation of, a liquid cooling loop.

This liquid cooling loop may place the data processing system in the operable conditions by providing a means for re-cooling a warmed cooling liquid of the liquid cooling loop to enhance regulation of heat that may be generated by hardware components of the data processing system while thermal components of the data processing system are connected in series with one another as part of the liquid cooling loop. By doing so, embodiments disclosed herein may reduce the likelihood of such aforementioned services being negatively impacted (e.g., delayed and/or prevented entirely).

In an embodiment, a data processing system for providing computer-implemented services is provided.

The data processing system may include: a plurality of heat generating components; and a liquid cooling loop to thermally manage the plurality of heat generating components, the liquid cooling loop being adapted to: obtain a cooling liquid from an external cooling system, the cooling liquid being cooled to a first temperature; cool a first heat generating component of the plurality of heat generating components using the cooling liquid to obtain a warmed cooling liquid; cool the warmed cooling liquid to obtain a re-cooled cooling liquid of a second temperature; and cool a second heat generating component of the plurality of heat generating components using the re-cooled cooling liquid.

The data processing system may further include a chassis in which the liquid cooling loop and the plurality of heat generating components are positioned.

Different ones of the heat generating components may have different thermal dissipation requirements.

The first temperature may be based on the first heat generating component and the second temperature may be based on the second heat generating component.

The liquid cooling loop may include: a thermal dissipator adapted to cool the warmed cooling liquid to obtain the re-cooled cooling liquid.

The data processing system may further include: an airflow generating component adapted to cool an addition heat generating component that is not a member of the plurality of heat generating components; and cool the thermal dissipator.

The liquid cooling loop may further include: a plurality of sections to carry the cooling liquid proximate to the plurality of heat generating components.

The liquid cooling loop may further include connection sets between the plurality of sections, the connections sets being adapted to receive, at least, the thermal dissipator to change a position of the thermal dissipator in the liquid cooling loop.

The liquid cooling loop may further include: a first cooling block to cool the first heat generating component; and a second cooling block to cool the second heat generating component.

The first cooling block, the second cooling block, and the thermal dissipator may be in series with each other in the liquid cooling loop.

In an embodiment, a liquid cooled chassis for thermal management of data processing systems is provided.

In an embodiment, a rack system for managing (e.g., thermally) data processing systems is provided.

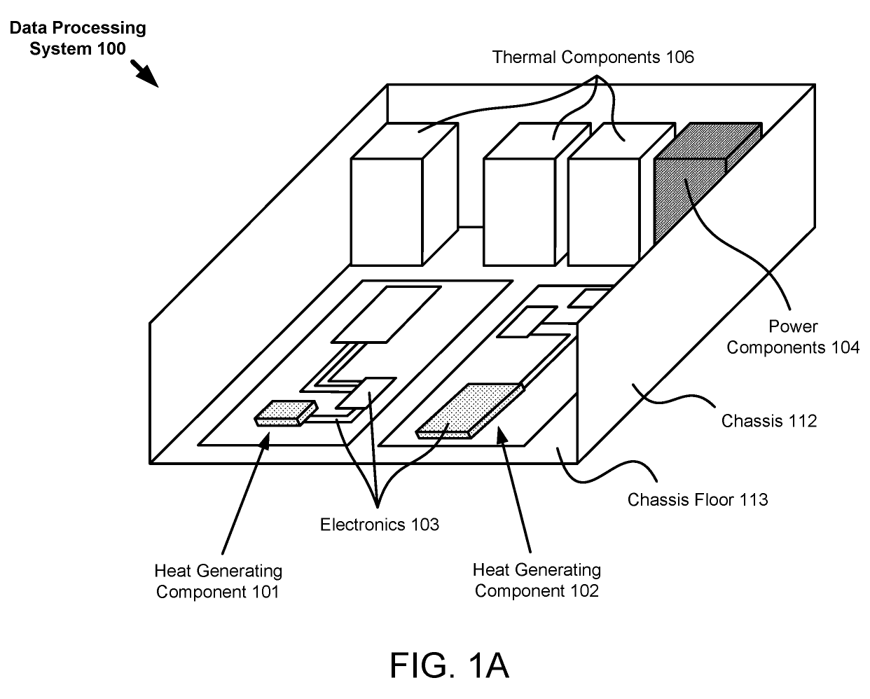

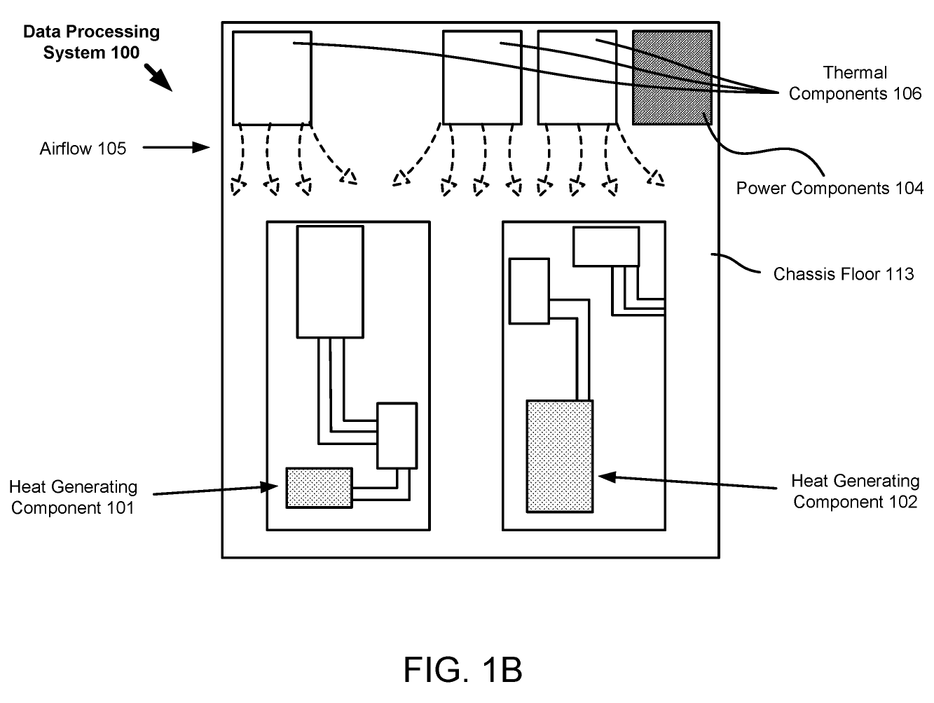

Turning to FIG. 1A, a first block diagram illustrating a data processing system (e.g., 100) in accordance with an embodiment is shown. The data processing system shown in FIG. 1 may provide computer implemented services, as discussed below.

The computer implemented services may include any type and quantity of computer implemented services. The computer implemented services may include, for example, database services, data processing services, electronic communication services, and/or any other services that may be provided using one or more computing devices. The computer implemented services may be provided by, for example, any portion of data processing system 100, and/or any other type of devices not to be limited by embodiments discussed herein.

Other types of computer implemented services may be provided by the system shown in FIG. 1 without departing from embodiments disclosed herein.

To provide the computer implemented services, data processing systems may include any number of hardware components. For example, operation of the any number of hardware components may facilitate various functionalities of a data processing system, thereby causing the data processing system to provide the computer implemented services. For example, to facilitate the various functionalities, a hardware component may transmit data to and/or from other devices via various avenues of communication. For example, such avenues of communication may depend on physical operable connections that directly connect multiple hardware components to one another.

However, such hardware components may generate heat while facilitating any number of the functionalities as a byproduct of those functionalities. Consequently, if such heat is not properly regulated (e.g., dissipated) to remain within an operational threshold (e.g., a thermal range) of the data processing system, the computer implemented services may be negatively impacted (e.g., may be delayed and/or prevented entirely). For example, excessive heat may physically damage the hardware components.

To improve the likelihood of providing the computer implemented services as expected and/or desired by a consumer of such services, a combination of liquid and air heat transport/dissipation may be utilized. For example, the data processing system may have a liquid cooling loop equipped to a chassis that houses the hardware components for the data processing system. This liquid cooling loop may facilitate traversal of a cooling liquid, for example, within a boundary of the chassis, the traversal running proximate to the hardware components, and the cooling liquid’s proximate traversal to the hardware components causing a transference of the heat generated by the hardware components to the cooling liquid.

By doing so, the now-warmed cooling liquid may continue to flow through the liquid cooling loop and have the transferred heat be dissipated by any number of means (e.g., by an airflow occurring proximate to the warmed cooling liquid), the heat being dissipated away from the hardware components (and therefore, the data processing system) and such dissipation of the heat resulting in the cooling liquid being re-cooled.

Additionally, it will be appreciated then that such dissipation may be based on a thermal delta of two or more mediums between which the heat may be transferred. For example, an optimal speed and/or an optimal efficiency of the heat dissipation from the cooling liquid to air flowing proximate to the cooling liquid throughout an ambient environment may be based on a thermal gradient (e.g., delta) between the cooling liquid and the air being maintained within an optimal range as defined by thermal dissipation requirements for each of the hardware components. Consequently, should the optimal range for the thermal gradient not be maintained, the thermal gradient therefore being above or below the optimal range, the hardware components (and therefore their respective functionalities) may be negatively impacted (e.g., via unpredictable and/or undesirable changes to the liquid cooling loop such as changes in (i) the liquid cooling loop’s inlet and/or outlet temperatures of the cooling liquid as it traverse, (ii) pressure within the loop’s interior, (iii) a flow rate of the liquid cooling system through the interior, etc.). Negatively impacting the hardware components (and/or the liquid cooling loop) may, in turn, negatively impact the computer implemented services (e.g., such services being delayed and/or prevented entirely).

Therefore, to increase the likelihood of providing the computer implemented services as expected and/or required by a consumer of such services, a rate of dissipation may be managed to meet the previously mentioned thermal dissipation requirements of the hardware components.

To do so, the liquid cooling loop may facilitate re-cooling of the cooling liquid (i) after the cooling liquid has been used to cool at least one heat generating component (e.g., resulting in a warmed cooling liquid), and (ii) before cooling a last heat generating component (e.g., last with respect to thermal components connected in series as part of the liquid cooling loop, the last heat generating component being cooled by a last thermal component to receive the (re-cooled) cooling liquid in the series).

To provide the above noted functionality, the system of FIG. 1 may include data processing system 100.

Data processing system 100 may include electronics 103, chassis 112, power components 104, and thermal components 106. Each of these is discussed below.

Electronics 103 may include at least a portion of the any number of hardware components, and as noted above, may provide computer implemented services. Hardware components of electronics 103 may be positioned on circuit cards and may generate heat while operating. These circuit cards may be pieces of circuit boards, for example, and this generated heat may be generated by, for example, heat generating component 101 and/or heat generating component 102. For example, and for future example scenarios discussed herein, assume heat generating component 101 and heat generating component 102 are processors of data processing system 100 (either one being a central processing unit (CPU) and/or a graphics processing unit (GPU)).

Electronics 103 and/or any other components of the any number of hardware components of data processing system 100 may be positioned in chassis 112 (e.g., housed in chassis 112). Chassis 112 may include an enclosure in which physical structures of electronics 103 (e.g., processors, memory, etc.), and/or other components of data processing system 100 may be positioned (e.g., positioned on chassis floor 113, a wall-like structure that protects an underneath side of the any number of hardware components and that is a bottom side of the enclosure that is chassis 112). For example, chassis 112 may facilitate placement and management of electronics 103 and/or other components (e.g., power components 104 and/or thermal components 106) in computing environments such as those discussed herein, chassis 112 being implemented by, for example, a rack mount frame of a rack mount chassis system.

Power components 104 (e.g., depicted using a patterned in-fill) may power the any number of hardware components of data processing system 100 (e.g., electronics 103). In some cases, for example, power components 104 may be implemented using power supplies. In other cases, for example, power components may be implemented using power rails and/or other types of operable connections that receive/distribute power provided by a busbar that distributes power throughout, for example, a rack system with which any number of data processing systems may be positioned. Such power may be provided to the busbar by power supplies, for example.

Furthermore, operation of these power supplies and any other power components may also contribute to the generation of heat. If left unregulated, this generation of heat may increase a likelihood of negatively impacting the components, and therefore, the providing of the computer implemented services by said components.

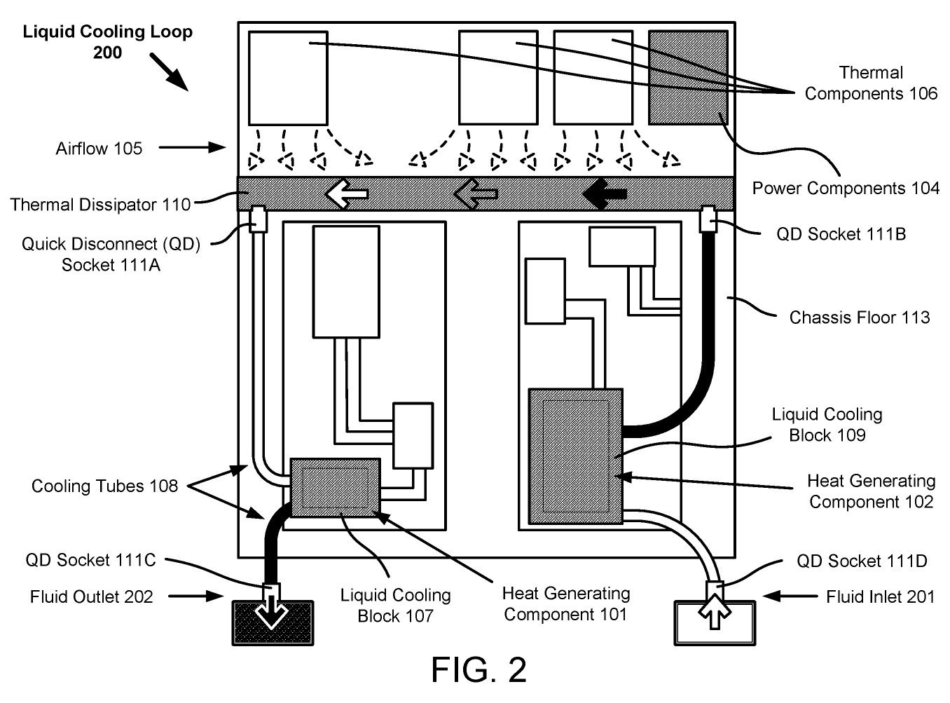

To manage the heat, data processing system 100 may include thermal components 106. Thermal components 106 may thermally manage any of the components of data processing system 100 (e.g., electronics 103 and/or power components 104). For example, thermal components 106 may include components such as cooling fans, coolant reservoirs, receiving elements for coolant, coolant (e.g., the cooling liquid), circulation pumps, manifolds or other types of flow control components, and/or other components to facilitate performance of liquid and/or air -based cooling of at least some of the any number of hardware components. For example, thermal components 106 may be used with a liquid cooling loop as discussed further below with regard to FIG. 2, and fans that facilitate airflow within chassis 112 to thereby cool heat generated by, for example, power components 104.

Turning to FIG. 1B, a second block diagram illustrating a data processing system (e.g., 100) in accordance with an embodiment is shown. The data processing system shown in FIG. 1B may be a same data processing system as that shown and discussed with regard to FIG. 1A. However, in contrast to the viewpoint of FIG. 1A, FIG. 1B may include a top-down view of data processing system 100, any of the any number of hardware components housed within chassis 112 being positioned above chassis floor 113 and illustrated in FIG. 1B as being within a boundary of chassis floor 113.

As previously discussed, thermal components 106 may include components such as cooling fans. These cooling fans may facilitate the airflow within chassis 112 in an attempt to cool down various components housed in chassis 112 via air-based heat dissipation.

As shown in FIG. 1B, such air-based heat dissipation may be based on airflow 105, depicted using curved and dashed arrows illustrated as extending away from thermal components 106 and towards the rest of chassis 112’s interior (e.g., electronics 103).

While illustrated in FIGS. 1A-1B with a limited number of specific components, a system may include additional, fewer, and/or different components without departing from embodiments disclosed herein.

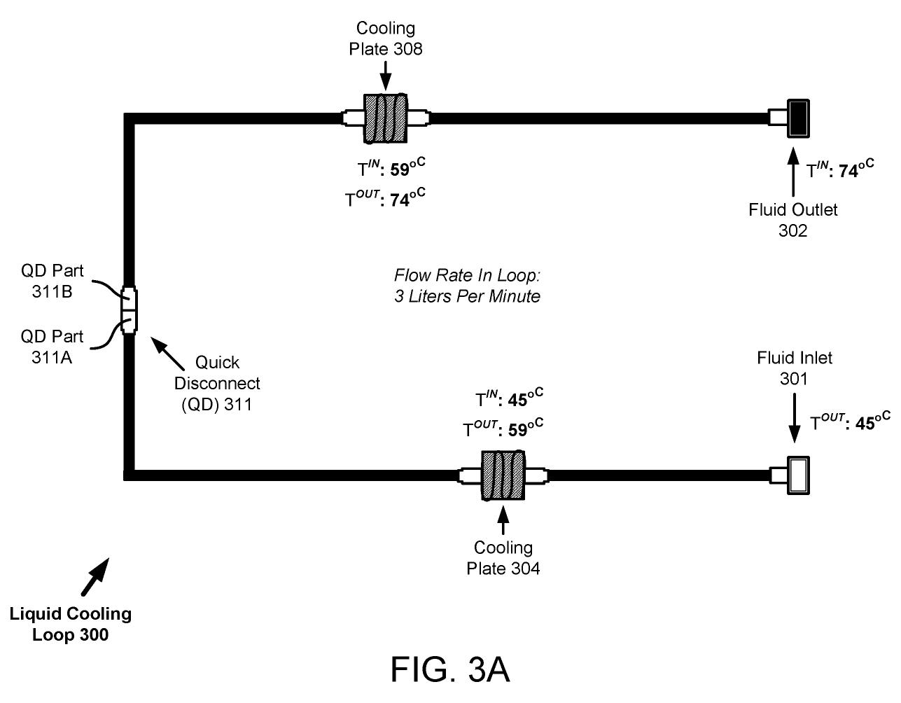

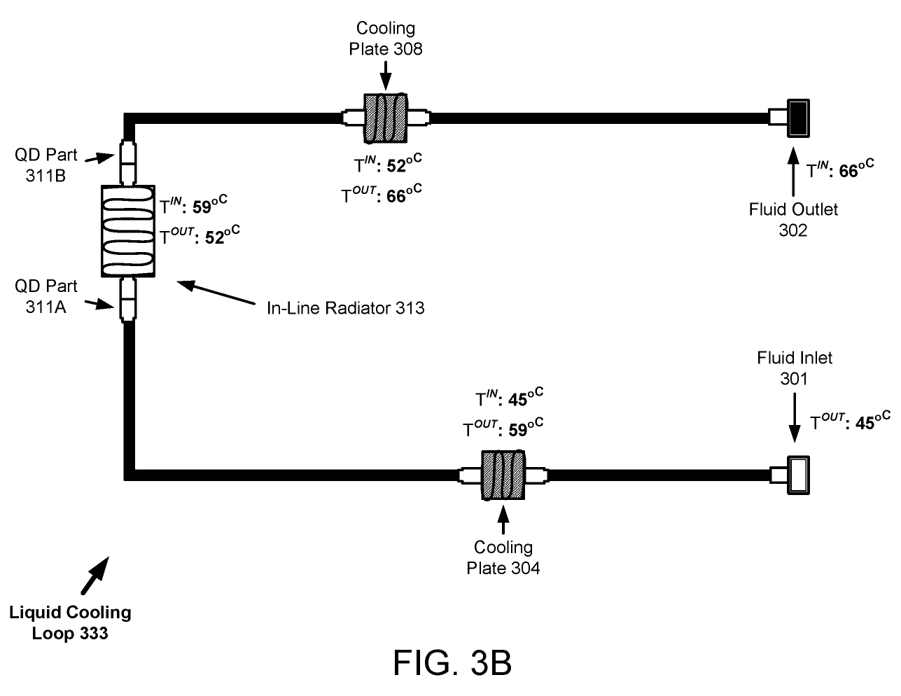

To further clarify embodiments disclosed herein, a diagram illustrating a data processing system (and/or portions thereof) and a liquid cooling system in accordance with embodiments is shown and discussed with regard to FIG. 2, below. Furthermore, diagrams illustrating examples of a liquid cooling loop in accordance with embodiments are shown and discussed further below with regard to FIGS. 3A-3B as well.

Turning to FIG. 2, a diagram illustrating a data processing system (e.g., 100) and a liquid cooling loop (e.g., 200) in accordance with an embodiment is shown. The data processing system shown in FIG. 2 may provide computer implemented services, as previously discussed, as well as discussed further below. The liquid cooling loop shown in FIG. 2 may provide thermal management for the data processing system as it provides the computer implemented services, also discussed further below.

As discussed with regard to FIGS. 1A-1B, chassis 112 may be implemented by an enclosure to house hardware components of data processing system 100, the enclosure being, for example, a rack mount frame or a similarly capable housing structure.

To provide the computer implemented services, these hardware components may operate to facilitate functionalities of data processing system 100. Such hardware components may, as a byproduct of their operation, generate heat. For example, such components may be implemented by heat generating component 101 and heat generating component 102, previously discussed.

Each of heat generating components 101-102 may have respective thermal dissipation requirements that if not met, may result in their own and/or system-wide overheating (e.g., affecting components of data processing system 100 unpredictably), thereby being likely to negatively impact the computer implemented services.

Therefore, to increase the likelihood of providing the computer implemented services as expected and/or required by a consumer of such services, a rate of dissipation may be managed to meet the previously mentioned thermal dissipation requirements of the hardware components. To do so, liquid cooling loop 200 may be positioned (e.g., installed) with data processing system 100 as shown, for example, in FIG. 2.

Liquid cooling loop 200 may, for example, (i) obtain a cooling liquid from an external cooling system, the cooling liquid being cooled to a first temperature, (ii) cool a first heat generating component (e.g., 101) of a plurality of heat generating components housed in chassis 112 using the cooling liquid to obtain a warmed cooling liquid, (iii) cool the warmed cooling liquid to obtain a re-cooled cooling liquid of a second temperature, and (iv) cool a second heat generating component (e.g., 102) of the plurality of heat generating components using the re-cooled cooling liquid.

It will be appreciated that the external cooling system may include, for example, manifolds from which, respectively, the cooling liquid may be obtained and/or to which the cooling liquid may be directed such as via fluid inlet 201 and fluid outlet 202.

To provide its functionality, liquid cooling loop 200 may include fluid inlet 201, cooling tubes 108, liquid cooling block 109, liquid cooling block 107, thermal dissipator 110, quick disconnect (QD) sockets(111A-111D), and fluid outlet 202. Each of these is discussed below.

Fluid inlet 201 may allow cooling liquid to enter a flow-path of (e.g., through) liquid cooling loop 200, the cooling liquid being from an external (e.g., outside chassis 112 and/or liquid cooling loop 200) source of the cooling liquid such as one of the previously mentioned manifolds.

To provide its functionality, fluid inlet 201 may be implemented by, for example, at least a portion of the source of the cooling liquid, a connection between the source and the flow-path, and a beginning portion of the flow-path through which the cooling liquid is introduced to the system of FIG. 2. For example, as shown in FIG. 2, the manifold (e.g., cooling liquid source) is illustrated with an arrow pointing from its interior to (e.g., through) a fluid line that extends away from fluid inlet 201 and extends toward chassis 112 until within the interior of chassis 112. The connection between the fluid line and the manifold may be implemented by quick disconnect (QD) socket 111D, such quick disconnect (QD) socket connections being reliably used for liquid cooling of distributed systems. The fluid line may simply be tubes capable of directing the cooling liquid along the flow-path, this fluid line being, for example, a part of cooling tubes 108, discussed below.

Cooling tubes 108 may, as mentioned above, direct the cooling liquid along the flow-path through liquid cooling loop 200, thereby allowing fluid communication through the liquid cooling loop and between each of the components of liquid cooling loop 200 until the cooling liquid is dispensed from liquid cooling loop 200.

It will be appreciated that while only labeled on a left side of the page, cooling tubes 108 may include the fluid lines that start from fluid inlet 201 and direct the cooling liquid through a first liquid cooling block (e.g., 109), through a thermal dissipator (e.g., 110), through a second liquid cooling block (e.g., 107), and out through a fluid outlet (e.g., 202).

To provide its functionality, cooling tubes 108 may be implemented by, for example, hollow, tubular structures in which the cooling liquid may flow, these hollow tubular strictures being connected to one another via devices and/or connection mechanisms (e.g., quick disconnect (QD) sockets 111A-111D, discussed below).

quick disconnect (QD) sockets 111A-111D may facilitate connections along liquid cooling loop 200 such that the flow-path may be sealed for the cooling liquid to flow through without worry of leaks and/or unstable pressure causing undesirable impacts to data processing system 100.

To provide its functionality, quick disconnect (QD) sockets 111A-111D may be implemented by, for example, quick disconnect sockets whose operable connections are based on pressure applied to sub-components of the quick disconnect sockets.

Liquid cooling block 109 may facilitate a dissipation of heat generated by, for example, heat generating component 102 by facilitating (e.g., along with liquid cooling block 107) circulation of the cooling liquid through, for example, cooling tubes 108 throughout liquid cooling loop 200. To do so, liquid cooling block 109 may operate in a similar manner as that of a heat sink and a liquid cooling pump. For example, such operation of liquid cooling block 109 may require that liquid cooling block 109 be placed with heat generating component 102. By positioning liquid cooling block 109 with heat generating component 102, liquid cooling block 109 may facilitate, for example, (i) a traversal of the cooling liquid being pumped, such that the cooling liquid may traverse proximate to heat generating component 102 during heat generating component 102’s operation, (ii) a receiving of at least a portion of the heat generated by heat generating component 102 (e.g., via a heat sink-like structure of liquid cooling block 109), (iii) a dissipation of the at least a portion of the heat received into the cooling liquid as the cooling liquid is circulated through liquid cooling block 109 while proximate to heat generating component 102, and (iv) a dispense of the cooling liquid from liquid cooling block 109, such that the cooling liquid may traverse away from the heat generating component 102 during heat generating component 102’s operation. Thus, a transference of the at least a portion of the heat may be dissipated away from heat generating component 102.

To provide its functionality, liquid cooling block 109 may be implemented by, for example, a block-like component that includes a metal base made of a heat conducting material such as copper or aluminum, the metal base being adapted to sit on heat generating component 102 and allowing the at least a portion of the heat generated to be absorbed into the conducting material. In addition to the metal base, the block-like component make include an interior, or be positioned with some fluid lines such that proximate traversal of the cooling liquid may result in the heat absorbed into the metal base to be further absorbed into the cooling liquid (e.g., the fluid lines being positioned within this interior and/or otherwise positioned proximate to the metal base.

Liquid cooling block 107 may provide a same functionality as that of liquid cooling block 109, but rather than primarily dissipating heat generated by heat generating component 102, liquid cooling block 107 may primarily facilitate dissipation of heat generated by heat generating component 101.To provide its functionality, liquid cooling block 107 may be implemented by, for example, a block-like structure similar to that described above with respect to liquid cooling block 109.

Thermal dissipator 110 may (i) receive a warmed cooling liquid once the cooling liquid is warmed due the dissipation of heat from passing through liquid cooling block 109, (ii) direct the warmed cooling liquid along its interior, flowing the warmed cooling liquid generally from a right-hand side of thermal dissipator 110 to a left-hand side of thermal dissipator 110 (e.g., depicted using arrows pointing from right to left on thermal dissipator 110, the arrows starting off with dark shading that gets progressively lighter as they are depicted further and further to the left-hand side) all the while airflow 105 traversing proximate to the surface area of thermal dissipator 110 resulting in the warmed cooling liquid to be re-cooled to obtain a re-cooled cooling liquid once reaching the left-hand side of thermal dissipator 110, and (iii) dispensing of the re-cooled cooling liquid to provide the re-cooled cooling liquid to liquid cooling block 107.

For example, thermal dissipator 110 may be implemented by the above-mentioned

To provide its functionality, thermal dissipator 110 may be implemented by, for example, a radiator positioned within chassis 112’ interior and positioned to be in thermal communication with at least a portion of thermal components 106. For example, airflow 105 caused by fans blowing air through chassis 112’s interior may assist in the dissipation of heat absorbed to the radiators surface area from the warmed cooling liquid, enough of the dissipation resulting in the re-cooling of the warmed cooling liquid to obtain the re-cooled cooling liquid.

Fluid outlet 202 may allow the cooling liquid to exit the flow-path of (e.g., dispense from) liquid cooling loop 200, cooling liquid being dispensed such that the cooling liquid is then received by the previously mentioned manifolds via fluid outlet 202 via a connection mechanism such as quick disconnect (QD) socket 111C.

To provide its functionality, fluid outlet 202 may be implemented by, for example, at least a portion of a destination of the cooling liquid, a connection between the destination and the flow-path, and an ending portion of the flow-path through which the cooling liquid is dispensed from the system of FIG. 2. For example, as shown in FIG. 2, fluid outlet 202 is illustrated with an arrow pointing into one of the manifolds from (e.g., through) a fluid line that extends away from liquid cooling block 107 and extends toward fluid outlet 202. The connection between the fluid line and fluid outlet 202 may be implemented by quick disconnect (QD) socket 111C, such quick disconnect (QD) sockets connections being reliably used for liquid cooling of distributed systems. The fluid line may simply be tubes capable of directing the cooling liquid along the flow-path, this fluid line being, for example, a part of cooling tubes 108, previously discussed.

Although discussed with regard to a liquid cooling loop’s (e.g., 200) flow-path through which the cooling liquid may be directed, it will be appreciated that a flow-path of at least a portion the liquid cooling loop housed at least partially by chassis 112 may include any shape and/or any structure of flow-path not to be limited by embodiments discussed herein.

Thus, liquid cooling loop 200 may include the above-discussed components to facilitate thermal management for hardware components of data processing system 100. Therefore, to do so, liquid cooling loop 200 may facilitate re-cooling of the cooling liquid (i) after the cooling liquid has been used to cool at least one heat generating component (e.g., resulting in a warmed cooling liquid), and (ii) before cooling a last heat generating component (e.g., last with respect to thermal components connected in series as part of the liquid cooling loop, the last heat generating component being cooled by a last thermal component to receive the (re-cooled) cooling liquid in the series.

While illustrated in FIG. 2 with a limited number of specific components, a system may include additional, fewer, and/or different components without departing from embodiments disclosed herein.

For additional information regarding how a thermal dissipator (e.g., 110) may be included in a liquid cooling loop (e.g., 200) to enhance thermal management for a system (e.g., 100), refer to the discussions of FIGS. 3A below and FIG. 3B further below.

Turning to FIG. 3A, a diagram illustrating a liquid cooling loop (e.g., 300) in accordance with an embodiment is shown. The liquid cooling loop shown in FIG. 3A may provide thermal management for, for example, data processing system 100 and/or any other data processing systems not explicitly shown in FIG. 3A who’s at least a portion of hardware components are at least partially cooled by thermal components of liquid cooling loop 300 connected in-series to one another.

It will be appreciated that liquid cooling loop 300 may be an example implementation of systems previously discussed. For example, liquid cooling loop 300 may thermally manage a single data processing system (e.g., as discussed with regard to liquid cooling loop 200 positioned to thermally manage data processing system 100), and/or any number of data processing systems such as those vertically stacked with regard to one another in a rack mount chassis system. For example, assume two or more data processing systems are stacked in a rack (not explicitly shown) for the following discussions of FIGS. 3A and 3B.

Each of these data processing systems may include, for example, a chassis in which the liquid cooling loop (e.g., 300) and a plurality of heat generating components are positioned. This chassis may resemble, at least in part, chassis and components discussed with regard to FIGS. 1A-2.

As previously discussed, different ones of the heat generating components may have different thermal dissipation requirements. These thermal dissipation requirements, to be met, may rely on managing various variables within liquid cooling loop 300. Such variables may include, for example, (i) inlet and outlet cooling liquid temperatures (e.g., T^{in and} T^{out}) for various thermal components, (ii) internal pressure of a thermal components, (iii) average temperature across a surface area of a thermal component, (iv) a flow rate of cooling liquid as it traverses its flow-path directed by liquid cooling loop 300, and/or (v) any other variables that if changed to no longer meet respective operating thresholds, may result in significant deviation from the heat dissipation requirements and thus, may be less likely to facilitate functionalities of hosted systems as expected and/or desired. Thus, computer implemented services that depend on such functionalities may be delayed and/or prevented entirely.

As shown in FIG. 3A, for example, liquid cooling loop 300 may receive cooling fluid from fluid inlet 301, direct the cooling fluid through a series of thermal components, and dispense the cooling fluid from fluid outlet 302.

By circulating the cooling liquid through liquid cooling loop 300, a first degree of thermal management may be implemented in an attempt to control the various variables on which meeting the operating thresholds depends.

However, due to thermal components of liquid cooling loop 300 being connected in-series with one another as shown in FIG. 3A, heat absorbed into the cooling liquid may warm the cooling liquid, thereby resulting in a warmed cooling liquid that, in turn, contributes to a higher inlet temperature of subsequent thermal components. This warmed cooling liquid, due to having a reduced thermal delta with regard to each respective temperature of subsequent thermal components in the series, may be less likely to effectively dissipate heat from said subsequent thermal components in a manner that meets the heat dissipation requirements of respectively and subsequently associated heat generating components of the subsequent thermal components.

For example, as shown in FIG. 3A between fluid inlet 301 and fluid outlet 302 and along liquid cooling loop 300, two types of components are illustrated. These two types of components are, for example, (i) cooling plates (having similar functionality to that of the previously discussed liquid cooling blocks) and (ii) quick disconnect (QD) sockets that connect portions of fluid lines to one another such that liquid cooling loop 300 is sealed, extends far enough to adequately cover the entire system, and allows for system structure adaptability (e.g., allows other components to be included).

These quick disconnect (QD) sockets may include quick disconnect (QD) sockets 311A-311B and may each have an outlet temperature that is equal to its inlet temperature. This may be due to, for example, the quick disconnect (QD) sockets not being adapted for facilitating heat dissipation.

The cooling plates may include cooling plates 304 and 308 and may each have an outlet temperature that is higher than each’s inlet temperature. This may be due to, for example, the generating of heat as a byproduct of a corresponding heat generating component’s operation. The functionality of such cooling plates may be to facilitate heat dissipation for said component, therefore, as any of the cooling plates being able to absorb at least a portion of generated heat, that generated heat may cause both a surface area temperature of the cooling plate in question to increase as well as warming the cooling liquid before the now warmed cooling liquid.

For example, assume that liquid cooling loop 300 includes the cooling liquid traversing a flow-path of the loop with a 3 liters per minute flow rate. Additionally, assume for simplicity that thermal dissipation requirements associated with liquid cooling loop 300 may indicate that the cooling liquid must remain within a temperature range from 42^{oC to} 70^{oC} from anywhere within the loop, any temperature of the cooling liquid over above 70^{oC} or under 42^{oC}, may impact the system being thermally managed by liquid cooling loop 300 unpredictably (e.g., and/or undesirably).

A first temperature of the cooling liquid, as shown in FIG. 3A, may be 45^{oC} based on a first heat generating component (e.g.,101), and a second temperature may be based on a second heat generating component, discussed further below. Thus, as the cooling liquid passes through (a first) cooling plate 304, we see an inlet temperature of 45^{oC} and an outlet temperature of 59^{oC}. It will be appreciated that these observations illustrate that the cooling liquid may acquire progressively increasing temperatures as the cooling liquid traverses in-series to facilitate heat dissipation for the thermal components (the cooling plates).

Now assume, for example, that while still monitoring the loop, cooling plate 308 may be subjected to a small degree of overheating when its surface area temperature rises above its respective operating threshold levels. Consequently, we may observe an inlet temperature of 59^{oC} and an outlet temperature of 74^{oC}. However, upon observing the outlet temperature of 74^{oC} it may be deduced that time is of the essence with regard to regulating such heat back to be within desirable levels below 70^{oC} in order to meet the thermal dissipation requirements to, in turn, allow such thermally managed systems to facilitate providing the computer implemented services as expected and/or required by consumers of said services.

However, as shown in FIG. 3A, liquid cooling loop 300 does not include, for example, a thermal dissipator (110, discussed previously with regard to FIG. 2.) that allowed for cooling of warmed cooling liquid prior to continuing on the flow-path through subsequent thermal components.

For example, because this loop lacks the thermal dissipator, subsequent outlet temperatures may be observed at 74^{oC}. Consequently, by increasing to 74^{oC}, and having been above the threshold of 70^{oC} from the thermal dissipation requirements for an extended amount of time, the warmed cooling liquid may continue to warm throughout its traversal, thereby increasing how likely such thermally managed systems may be negatively impacted (e.g., unpredictably), and the provided services likely to also be negatively impacted.

Therefore, to increase the likelihood of providing the computer implemented services as expected and/or desired, the thermal dissipator (e.g., a radiator) may be placed in fluid/thermal communication with the liquid cooling loop (300) to re-cool the warmed cooling liquid, thereby resulting in the cooling liquid being capable of progressing through the flow-path without exceeding the 70^{oC} threshold level from the thermal dissipation requirements.

To place the thermal dissipator with liquid cooling loop 300, some connections points such as quick disconnect (QD) socket 311 may be disconnected to allow the thermal dissipator to be placed in the loop. For example, quick disconnect (QD) socket 311 may be disconnected to obtain quick disconnect (QD) socket part 311A and quick disconnect (QD) socket part 311B, discussed further below with regard to FIG. 3B.

For additional information regarding how the above-mentioned limitation (e.g., progressive warming of the cooling liquid) on liquid cooling components connected in series with one another may be addressed (e.g., via inclusion of the thermal dissipator) to increase a likelihood of the liquid cooling loop meeting the also above-mentioned heat dissipation requirements, refer to FIG. 3B, further below.

Turning to FIG. 3B, a diagram illustrating a liquid cooling loop (e.g., 333) in accordance with an embodiment is shown. The liquid cooling loop shown in FIG. 3B may provide thermal management for a data processing system (e.g., 100), and/or any additional data processing systems included with the data processing system positioned in a rack. This thermal management may be performed in a manner that meets the aforementioned heat dissipation requirements of hardware components of the data processing system, and/or of the additional data processing systems, to decrease a likelihood of negatively impacting the computer implemented services to be provided by said data processing system and/or said data processing systems.

Additionally, it will be appreciated that liquid cooling loop 333 may be the previously discussed liquid cooling loop (e.g., 300), but with the inclusion of a thermal dissipator (e.g., in-line radiator 313) as discussed in FIG. 3A.

For example, liquid cooling loop 333 is illustrated to include in-line radiator 313 while liquid cooling loop 300 is not.

Therefore, it will be further appreciated that while liquid cooling loop 300 is subject to progressively higher inlet temperatures of the cooling liquid for each respective thermal component connected in-series to the cooling liquid’s flow-path, liquid cooling loop 333 may be adapted to re-cool the cooling liquid once warmed by a one of the thermal components. By doing so, undesirable temperatures of the cooling liquid may be prevented from reaching outside of the thermal dissipation requirements previously discussed. Such undesirable inlet temperatures may, for example, exceed operable condition thresholds, thereby being likely to result in damage to the system.

It will be appreciated that, as previously discussed, in-line radiator 313 may be positioned between (and therefore connected to) quick disconnect (QD) socket part 311A and quick disconnect (QD) socket part 311B to facilitate the fluid communication and/or the thermal communication.

For example, when cooling plate 308 had the warmed cooling liquid pass through its interior, the inlet temperature of 59^{oC} and the outlet temperature of 74^{oC} was observed.

Therefore, to provide such thermal regulation, in-line radiator 313 may receive warmed cooling liquid via the flow-path through liquid cooling loop 333. The inlet temperature being, for example, the inlet temperature of 59^{oC}. However, as the warmed cooling liquid traverses in-line radiator 313’s interior, the warmed cooling liquid may be re-cooled by the warmed cooling liquid’s absorbed heat (obtained during traversal of the flow-path) dissipating via the in-line radiator’s (313) thermally conductive surfaces, this dissipation of heat being further aided/facilitated by other thermal components such as, for example, the fans discussed with respect to FIG. 2 that may be adapted to direct airflow 105 within chassis 112’s interior. For example, airflow similar to airflow 105 may flow proximate to the thermally conductive surface of in-line radiator 313 to further facilitate an effective rate of heat dissipation. By doing so, in-line radiator 313 may dispense the cooling liquid with an outlet temperature of 52^{oC}.

Consequently, the subsequent temperatures of the cooling liquid (e.g., when flowing through the subsequent thermal components in-series and along the flow-path) may not be observed as exceeding the threshold level of 70^{oC} (e.g., as shown in FIG. 3B) before the cooling liquid is dispensed via fluid outlet 302 (e.g., and thereby being flowed into fluid-receiving manifold 322). For example, cooling plate 308 may be observed to have an inlet temperature of 52^{oC} and an outlet temperature of 66^{oC}, thereby remaining within the thermal dissipation requirements previously discussed.

Thus, to increase the likelihood of providing the computer implemented services as expected and/or desired, a thermal dissipator (e.g., in-line radiator 313) may be placed in fluid/thermal communication with a liquid cooling loop (e.g., 300) to re-cool warmed cooling liquid in between thermal communications involving heat absorption (causing the cooling liquid to be warmed) by the cooling liquid, and , thereby resulting in the cooling liquid being capable of progressing through the flow-path without exceeding the 70^{oC} threshold level, and therefore maintaining thermal dissipation requirements for the heat generating components.

Any of the processes and/or components illustrated in and/or discussed with regard to FIGS. 1A-3B may be implemented with and/or used in conjunction with one or more computing devices (e.g., a computing device (e.g., 100) may be equipped with a liquid cooling loop (e.g., 200) that utilizes a thermal dissipator (e.g., 110) for facilitating thermal management of the system where the cooling liquid may be re-cooled in between flowing through 2 or more thermal components such as liquid cooling blocks 107 and 109.).

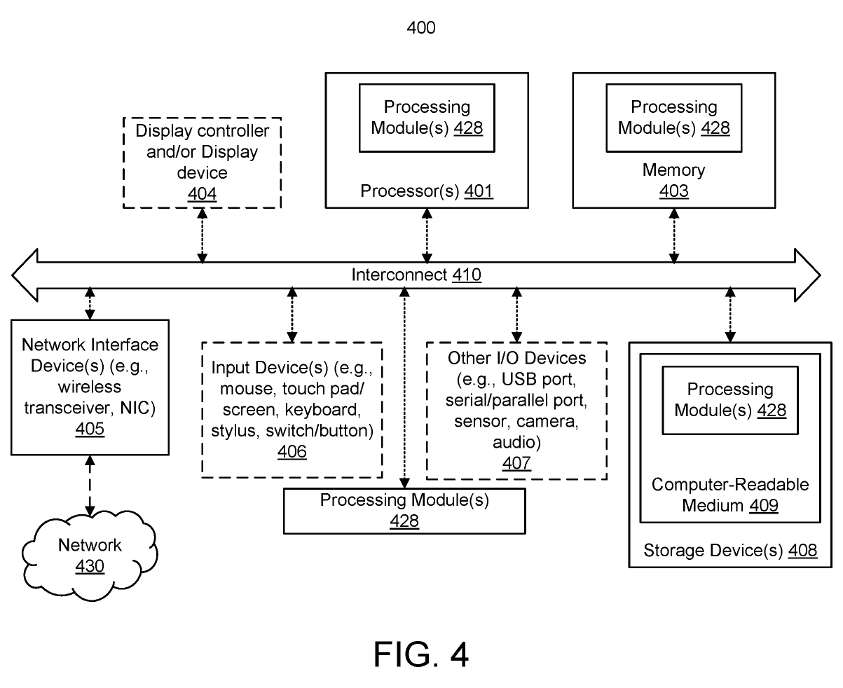

Turning to FIG. 4, a block diagram illustrating an example of a data processing system (e.g., a computing device) in accordance with an embodiment is shown. For example, system 400 may represent any of data processing systems described above performing any of the processes or methods described above. System 400 can include many different components. These components can be implemented as integrated circuits (ICs), portions thereof, discrete electronic devices, or other modules adapted to a circuit board such as a motherboard or add-in card of the computer system, or as components otherwise incorporated within a chassis of the computer system. Note also that system 400 is intended to show a high-level view of many components of the computer system. However, it is to be understood that additional components may be present in certain implementations and furthermore, different arrangement of the components shown may occur in other implementations. System 400 may represent a desktop, a laptop, a tablet, a server, a mobile phone, a media player, a personal digital assistant (PDA), a personal communicator, a gaming device, a network router or hub, a wireless access point (AP) or repeater, a set-top box, or a combination thereof. Further, while only a single machine or system is illustrated, the term “machine” or “system” shall also be taken to include any collection of machines or systems that individually or jointly execute a set (or multiple sets) of instructions to perform any one or more of the methodologies discussed herein.

In one embodiment, system 400 includes processor 401, memory 403, and devices 405-407 via a bus or an interconnect 410. Processor 401 may represent a single processor or multiple processors with a single processor core or multiple processor cores included therein. Processor 401 may represent one or more general-purpose processors such as a microprocessor, a central processing unit (CPU), or the like. More particularly, processor 401 may be a complex instruction set computing (CISC) microprocessor, reduced instruction set computing (RISC) microprocessor, very-long instruction word (VLIW) microprocessor, or processor implementing other instruction sets, or processors implementing a combination of instruction sets. Processor 401 may also be one or more special-purpose processors such as an application specific integrated circuit (ASIC), a cellular or baseband processor, a field programmable gate array (FPGA), a digital signal processor (DSP), a network processor, a graphics processor, a network processor, a communications processor, a cryptographic processor, a co-processor, an embedded processor, or any other type of logic capable of processing instructions.

Processor 401, which may be a low power multi-core processor socket such as an ultra-low voltage processor, may act as a main processing unit and central hub for communication with the various components of the system. Such processor can be implemented as a system on chip (SoC). Processor 401 is configured to execute instructions for performing the operations discussed herein. System 400 may further include a graphics interface that communicates with optional graphics subsystem 404, which may include a display controller, a graphics processor, and/or a display device.

Processor 401 may communicate with memory 403, which in one embodiment can be implemented via multiple memory devices to provide for a given amount of system memory. Memory 403 may include one or more volatile storage (or memory) devices such as random-access memory (RAM), dynamic RAM (DRAM), synchronous DRAM (SDRAM), static RAM (SRAM), or other types of storage devices. Memory 403 may store information including sequences of instructions that are executed by processor 401, or any other device. For example, executable code and/or data of a variety of operating systems, device drivers, firmware (e.g., input output basic system or BIOS), and/or applications can be loaded in memory 403 and executed by processor 401. An operating system can be any kind of operating systems, such as, for example, Windows® operating system from Microsoft®, Mac OS®/iOS® from Apple, Android® from Google®, Linux®, Unix®, or other real-time or embedded operating systems such as VxWorks.

System 400 may further include IO devices such as devices (e.g., 405, 406, 407, 408) including network interface device(s) 405, optional input device(s) 406, and other optional IO device(s) 407. Network interface device(s) 405 may include a wireless transceiver and/or a network interface card (NIC). The wireless transceiver may be a Wi-Fi transceiver, an infrared transceiver, a Bluetooth transceiver, a WiMAX transceiver, a wireless cellular telephony transceiver, a satellite transceiver (e.g., a global positioning system (GPS) transceiver), or other radio frequency (RF) transceivers, or a combination thereof. The NIC may be an Ethernet card.

Input device(s) 406 may include a mouse, a touch pad, a touch sensitive screen (which may be integrated with a display device of optional graphics subsystem 404), a pointer device such as a stylus, and/or a keyboard (e.g., physical keyboard or a virtual keyboard displayed as part of a touch sensitive screen). For example, input device(s) 406 may include a touch screen controller coupled to a touch screen. The touch screen and touch screen controller can, for example, detect contact and movement or break thereof using any of a plurality of touch sensitivity technologies, including but not limited to capacitive, resistive, infrared, and surface acoustic wave technologies, as well as other proximity sensor arrays or other elements for determining one or more points of contact with the touch screen.

IO devices 407 may include an audio device. An audio device may include a speaker and/or a microphone to facilitate voice-enabled functions, such as voice recognition, voice replication, digital recording, and/or telephony functions. Other IO devices 407 may further include universal serial bus (USB) port(s), parallel port(s), serial port(s), a printer, a network interface, a bus bridge (e.g., a PCI-PCI bridge), sensor(s) (e.g., a motion sensor such as an accelerometer, gyroscope, a magnetometer, a light sensor, compass, a proximity sensor, etc.), or a combination thereof. IO device(s) 407 may further include an imaging processing subsystem (e.g., a camera), which may include an optical sensor, such as a charged coupled device (CCD) or a complementary metal-oxide semiconductor (CMOS) optical sensor, utilized to facilitate camera functions, such as recording photographs and video clips. Certain sensors may be coupled to interconnect 410 via a sensor hub (not shown), while other devices such as an embedded controller (not shown) may control a keyboard or thermal sensor, dependent upon the specific configuration or design of system 400.

To provide for persistent storage of information such as data, applications, one or more operating systems and so forth, a mass storage (not shown) may also couple to processor 401. In various embodiments, to enable a thinner and lighter system design as well as to improve system responsiveness, this mass storage may be implemented via a solid-state device (SSD). However, in other embodiments, the mass storage may primarily be implemented using a hard disk drive (HDD) with a smaller amount of SSD storage to act as an SSD cache to enable non-volatile storage of context state and other such information during power down events so that a fast power up can occur on re-initiation of system activities. Also, a flash device may be coupled to processor 401, e.g., via a serial peripheral interface (SPI). This flash device may provide for non-volatile storage of system software, including a basic input/output software (BIOS) as well as other firmware of the system.

Storage device 408 may include computer-readable storage medium 409 (also known as a machine-readable storage medium or a computer-readable medium) on which is stored one or more sets of instructions or software (e.g., processing module, unit, and/or processing module/unit/logic 428) embodying any one or more of the methodologies or functions described herein. Processing module/unit/logic 428 may represent any of the components described above. Processing module/unit/logic 428 may also reside, completely or at least partially, within memory 403 and/or within processor 401 during execution thereof by system 400, memory 403 and processor 401 also constituting machine-accessible storage media. Processing module/unit/logic 428 may further be transmitted or received over a network 430 via network interface device(s) 405.

Computer-readable storage medium 409 may also be used to store some software functionalities described above persistently. While computer-readable storage medium 409 is shown in an exemplary embodiment to be a single medium, the term “computer-readable storage medium” should be taken to include a single medium or multiple media (e.g., a centralized or distributed database, and/or associated caches and servers) that store the one or more sets of instructions. The terms “computer-readable storage medium” shall also be taken to include any medium that is capable of storing or encoding a set of instructions for execution by the machine and that cause the machine to perform any one or more of the methodologies of embodiments disclosed herein. The term “computer-readable storage medium” shall accordingly be taken to include, but not be limited to, solid-state memories, and optical and magnetic media, or any other non-transitory machine-readable medium.

Processing module/unit/logic 428, components and other features described herein can be implemented as discrete hardware components or integrated in the functionality of hardware components such as ASICS, FPGAs, DSPs or similar devices. In addition, processing module/unit/logic 428 can be implemented as firmware or functional circuitry within hardware devices. Further, processing module/unit/logic 428 can be implemented in any combination hardware devices and software components.

Note that while system 400 is illustrated with various components of a data processing system, it is not intended to represent any particular architecture or manner of interconnecting the components as such details are not germane to embodiments disclosed herein. It will also be appreciated that network computers, handheld computers, mobile phones, servers, and/or other data processing systems which have fewer components, or (perhaps) more components may also be used with embodiments disclosed herein.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and (generally) conceived to be a self-consistent sequence of operations leading to a desired result. The operations are those requiring physical manipulations of physical quantities.

It should be borne in mind, however, that all of these and similar terms are to be associated with the appropriate physical quantities and are merely convenient labels applied to these quantities. Unless specifically stated otherwise as apparent from the above discussion, it is appreciated that throughout the description, discussions utilizing terms such as those set forth in the claims below, refer to the action and processes of a computer system, or similar electronic computing device, that manipulates and transforms data represented as physical (electronic) quantities within the computer system’s registers and memories into other data similarly represented as physical quantities within the computer system memories or registers or other such information storage, transmission or display devices.

Embodiments disclosed herein also relate to an apparatus for performing the operations herein. Such a computer program is stored in a non-transitory computer readable medium. A non-transitory machine-readable medium includes any mechanism for storing information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices).

The processes or methods depicted in the preceding figures may be performed by processing logic that comprises hardware (e.g., circuitry, dedicated logic, etc.), software (e.g., embodied on a non-transitory computer readable medium), or a combination of both. Although the processes or methods are described above in terms of some sequential operations, it should be appreciated that some of the operations described may be performed in a different order. Moreover, some operations may be performed in parallel rather than sequentially.

Embodiments disclosed herein are not described with reference to any particular programming language. It will be appreciated that a variety of programming languages may be used to implement the teachings of embodiments disclosed herein.

In the foregoing specification, embodiments have been described with reference to specific exemplary embodiments thereof. It will be evident that various modifications may be made thereto without departing from the broader spirit and scope of the embodiments disclosed herein as set forth in the following claims. The specification and drawings are, accordingly, to be regarded in an illustrative sense rather than a restrictive sense.

What is claimed is:

1. A data processing system comprising:
a plurality of heat generating components; and
a liquid cooling loop to thermally manage the plurality of heat generating components, the liquid cooling loop being adapted to:
obtain a cooling liquid from an external cooling system, the cooling liquid being cooled to a first temperature;
cool a first heat generating component of the plurality of heat generating components using the cooling liquid to obtain a warmed cooling liquid;
cool the warmed cooling liquid to obtain a re-cooled cooling liquid of a second temperature; and
cool a second heat generating component of the plurality of heat generating components using the re-cooled cooling liquid.

2. The data processing system of claim 1, further comprising a chassis in which the liquid cooling loop and the plurality of heat generating components are positioned.

3. The data processing system of claim 1, wherein different ones of the heat generating components have different thermal dissipation requirements.

4. The data processing system of claim 3, wherein the first temperature is based on the first heat generating component and the second temperature is based on the second heat generating component.

5. The data processing system of claim 1, wherein the liquid cooling loop comprises:
a thermal dissipator adapted to cool the warmed cooling liquid to obtain the re-cooled cooling liquid.

6. The data processing system of claim 5, wherein the data processing system further comprises:
an airflow generating component adapted to:
cool an addition heat generating component that is not a member of the plurality of heat generating components; and
cool the thermal dissipator.

7. The data processing system of claim 5, wherein the liquid cooling loop further comprises:
a plurality of sections to carry the cooling liquid proximate to the plurality of heat generating components.

8. The data processing system of claim 7, wherein the liquid cooling loop further comprises:
connection sets between the plurality of sections, the connections sets being adapted to receive, at least, the thermal dissipator to change a position of the thermal dissipator in the liquid cooling loop.

9. The data processing system of claim 5, wherein the liquid cooling loop further comprises:
a first cooling block to cool the first heat generating component; and
a second cooling block to cool the second heat generating component.

10. The data processing system of claim 9, wherein the first cooling block, the second cooling block, and the thermal dissipator are in series with each other in the liquid cooling loop.

11. A liquid cooled chassis, comprising:
a plurality of heat generating components; and
a liquid cooling loop to thermally manage the plurality of heat generating components, the liquid cooling loop being adapted to:
obtain a cooling liquid from an external cooling system, the cooling liquid being cooled to a first temperature;
cool a first heat generating component of the plurality of heat generating components using the cooling liquid to obtain a warmed cooling liquid;
cool the warmed cooling liquid to obtain a re-cooled cooling liquid of a second temperature; and
cool a second heat generating component of the plurality of heat generating components using the re-cooled cooling liquid.

12. The liquid cooled chassis of claim 11, wherein the liquid cooling loop comprises:
a thermal dissipator adapted to cool the warmed cooling liquid to obtain the re-cooled cooling liquid.

13. The liquid cooled chassis of claim 12, wherein the liquid cooled chassis further comprises:
an airflow generating component adapted to:
cool an addition heat generating component that is not a member of the plurality of heat generating components; and
cool the thermal dissipator.

14. The liquid cooled chassis of claim 12, wherein the liquid cooling loop further comprises:
a plurality of sections to carry the cooling liquid proximate to the plurality of heat generating components.

15. The liquid cooled chassis of claim 14, wherein the liquid cooling loop further comprises:
connection sets between the plurality of sections, the connections sets being adapted to receive, at least, the thermal dissipator to change a position of the thermal dissipator in the liquid cooling loop.

16. A rack system, comprising:
a rack; and
a data processing system to be housed in the rack, the data processing system comprising:
a plurality of heat generating components; and
a liquid cooling loop to thermally manage the plurality of heat generating components, the liquid cooling loop being adapted to:
obtain a cooling liquid from an external cooling system, the cooling liquid being cooled to a first temperature;
cool a first heat generating component of the plurality of heat generating components using the cooling liquid to obtain a warmed cooling liquid;
cool the warmed cooling liquid to obtain a re-cooled cooling liquid of a second temperature; and
cool a second heat generating component of the plurality of heat generating components using the re-cooled cooling liquid.

17. The rack system of claim 16, wherein the liquid cooling loop comprises:
a thermal dissipator adapted to cool the warmed cooling liquid to obtain the re-cooled cooling liquid.

18. The rack system of claim 17, wherein the data processing system further comprises:
an airflow generating component adapted to:
cool an addition heat generating component that is not a member of the plurality of heat generating components; and
cool the thermal dissipator.

19. The rack system of claim 17, wherein the liquid cooling loop further comprises:
a plurality of sections to carry the cooling liquid proximate to the plurality of heat generating components.

20. The rack system of claim 19, wherein the liquid cooling loop further comprises:
connection sets between the plurality of sections, the connections sets being adapted to receive, at least, the thermal dissipator to change a position of the thermal dissipator in the liquid cooling loop.
